(19) United States
(12) Patent Application Publication
(10) Pub. No.: US 2003/0072884 A1
(43) Pub. Date: Apr. 17, 2003

(54) Method of titanium and titanium nitride layer deposition

(75) Inventors: Tong Zhang, Palo Alto, CA (US); Hyoung-Chan Ha, Cupertino, CA (US); Jeong Soo Byun, Cupertino, CA (US); Avgerinos Gelatos, Redwood City, CA (US); Frederick C. Wu, Cupertino, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/978,140

(22) Filed: Oct. 15, 2001

(51) Int. Cl. B05D 5/12; C23C 16/00; H05H 1/00

(52) U.S. Cl. 427/255.391; 427/535; 427/79; 427/58

(57) ABSTRACT

A method of forming a film structure (e.g., film stacks) comprising titanium (Ti) and/or titanium nitride (TiN). The Ti film structure is formed by alternately depositing and then plasma treating thin films (less than about 100 Å thick) of titanium. The TiN film structure is formed by alternately depositing and then plasma treating thin films (less than about 300 Å thick) of titanium nitride. The titanium films are formed using a plasma reaction of titanium tetrachloride (TiCl₄) and a hydrogen-containing gas. The titanium nitride films are formed by thermally reacting titanium tetrachloride with a nitrogen-containing gas. The subsequent plasma treatment steps comprise a nitrogen/hydrogen-containing plasma.

### BACKGROUND OF THE DISCLOSURE

1. Field of the Invention

The invention relates to a method of thin film deposition and, more particularly to a method of forming titanium and/or titanium nitride films.

2. Description of the Background Art

In the manufacture of integrated circuits, a titanium and/or titanium nitride film is often used as a barrier layer to inhibit the diffusion of metals into regions underlying the barrier layer. These underlying regions include transistor gates, capacitor dielectric, semiconductor substrates, metal lines, and many other structures that appear in integrated circuits.

For example, when a gate electrode of a transistor is fabricated, a barrier layer is often formed between the gate material (e.g., polysilicon) and the metal (e.g., aluminum) of the gate electrode. The barrier layer inhibits the diffusion of the metal into the gate material. Such metal diffusion is undesirable because it potentially changes the characteristics of the transistor, rendering the transistor inoperable. A stack of titanium/titanium nitride (Ti/TiN) films, for example, is often used as a diffusion barrier.

The Ti/TiN stack has also been used to provide contacts to the source and drain of a transistor. For example, in a tungsten (W) plug process, a Ti layer deposited on a silicon (Si) substrate is converted to titanium silicide (TiSiₓ), followed by TiN layer deposition and tungsten (W) plug formation. The conversion of the Ti layer to TiSiₓ is desirable because the TiSiₓ forms a lower resistance contact to the silicon substrate then does the TiN layer. In addition to being a barrier layer, the TiN layer also serves two additional functions: 1) preventing chemical attack of TiSiₓ by tungsten hexafluoride (WF₆) during W plug formation; and 2) acting as a glue layer to promote adhesion of the W plug.

Ti and/or TiN layers are typically formed using physical and/or chemical vapor deposition techniques. A Ti/TiN combination barrier layer may be formed in a multiple chamber “cluster tool” by depositing a Ti film in one chamber followed by TiN film deposition in another chamber. For example, titanium tetrachloride (TiCl₄) may be reacted with different reactant gases to form both Ti and TiN films using CVD (e.g., under plasma conditions, Ti is formed when TiCl₄ reacts with hydrogen (H₂), and TiN is formed when TiCl₄ reacts with nitrogen (N₂)).

However, when a TiCl₄-based chemistry is used to form a Ti/TiN combination barrier layer, reliability problems can occur. In particular, if the Ti film thickness exceeds about 150 Å, the Ti/TiN stack can peel off an underlying field oxide layer or exhibit a haze, which may result, for example, from TiCl₄ or other species arising from TiCl₄, chemically attacking the Ti film prior to TiN deposition.

Another reliability problem can occur for TiN films. TiN films formed using CVD techniques at process temperatures greater than about 550° C., tend to have intrinsically high tensile stresses (e.g., tensile stress on the order of about 2×10¹⁰ dyne/cm² for a film thickness of about 200 Å). Since tensile forces increase with increasing film thicknesses, cracks can begin to develop in TiN films having thicknesses that exceed about 400 Å. When the process temperatures are reduced below about 500° C., thicker TiN films (e.g., thicknesses above about 1500 Å) having lower tensile stresses (e.g., tensile stress on the order of about 1-2×10⁹ dyne/cm²), without cracks can be produced. However, these low tensile stress TiN films typically have a high Cl content (e.g., chlorine content greater than about 3%). A high chlorine content is undesirable because the chlorine may migrate from the Ti/TiN film stack into the contact region of, for example the source or drain of a transistor, which can increase the contact resistance of such contact region and potentially change the characteristics of the transistor.

Therefore, a need exists in the art for a method of forming a reliable Ti and/or TiN films for integrated circuit fabrication.

### SUMMARY OF THE INVENTION

The present invention relates to a method of forming a film structure (e.g., film stack) comprising titanium (Ti) and/or titanium nitride (TiN) films. The Ti film is formed by alternately depositing and then plasma treating thin films (less than about 100 Å thick) of titanium. The TiN film is formed by alternately depositing and then plasma treating thin films (less than about 300 Å thick) of titanium nitride.

The titanium film is formed using a plasma reaction of titanium tetrachloride (TiCl₄) and a hydrogen-containing gas. The titanium nitride film is formed by thermally reacting titanium tetrachloride with a nitrogen-containing gas. The plasma treatment step comprises a nitrogen/hydrogen-containing plasma.

Alternatively, a TiSiₓ film is formed by alternately depositing and then plasma treating thin films (less than about 100 Å thick) of titanium formed on a silicon substrate. The TiSiₓ is formed using, for example, a plasma reaction between titanium tetrachloride (TiCl₄) and a hydrogen-containing gas. The plasma treatment step comprises a nitrogen/hydrogen-containing plasma.

### BRIEF DESCRIPTION OF THE DRAWINGS

The teachings of the present invention can be readily understood by considering the following detailed description in conjunction with the accompanying drawings, in which:

FIG. 1 depicts a schematic illustration of an apparatus that can be used for the practice of this invention;

FIGS. 2a-2e depict cross-sectional views of a substrate structure at different stages of integrated circuit fabrication incorporating a Ti/TiN film stack;

FIG. 3 is a graph of the resistivity and sheet resistance uniformity of a TiN film plotted as a function of the plasma treatment time;

FIG. 4 is a graph of the film stress for a TiN film plotted as a function of the plasma treatment time; and

FIGS. 5a-5b depict cross-sectional views of a capacitive structure at different stages of integrated circuit fabrication incorporating a TiN electrode.

### DETAILED DESCRIPTION

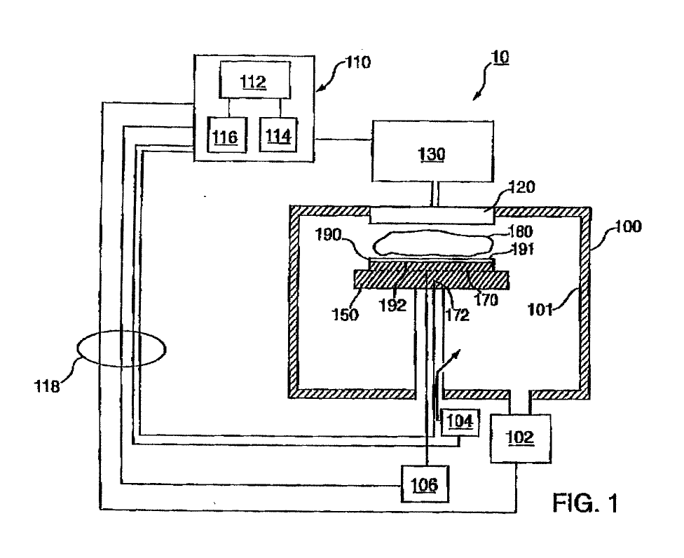

FIG. 1 depicts a schematic illustration of a wafer processing system 10 that can be used to practice embodiments of the present invention. The system 10 comprises a process chamber 100, a gas panel 130, a control unit 110, along with other hardware components such as power supplies 106 and vacuum pumps 102. One example of the process chamber 100 is a TiN chamber which has previously been described in commonly-assigned U.S. patent application Ser. No. 09/211,998, entitled “High Temperature Chemical Vapor Deposition Chamber”, filed on Dec. 14, 1998, which is herein incorporated by reference. The salient features of process chamber 100 are briefly described below.

Chamber 100

The process chamber 100 generally houses a support pedestal 150, which is used to support a substrate such as a semiconductor wafer 190 within the process chamber 100. The pedestal 150 can typically be moved in a vertical direction inside the chamber 100 using a displacement mechanism (not shown). Depending on the specific process, the semiconductor wafer 190 can be heated to some desired temperature prior to layer deposition.

In chamber 100, the wafer support pedestal 150 is heated by an embedded heater 170. For example, the pedestal 150 may be resistively heated by applying an electric current from an AC power supply 106 to the heater element 170. The wafer 190 is, in turn, heated by the pedestal 150, and can be maintained within a desired process temperature range of, for example, about 250° C. to about 750° C. A temperature sensor 172, such as a thermocouple, is also embedded in the wafer support pedestal 150 to monitor the temperature of the pedestal 150 in a conventional manner. For example, the measured temperature may be used in a feedback loop to control the electric current applied to the heater element 170 by the power supply 106, such that the wafer temperature can be maintained or controlled at a desired temperature which is suitable for the particular process application. The pedestal 150 is optionally heated using radiant heat (not shown).

A vacuum pump 102 is used to evacuate the process chamber 100 and to help maintain the proper gas flows and pressure inside the chamber 100. A showerhead 120, through which process gases are introduced into the chamber 100, is located above the wafer support pedestal 150.

A “dual-gas” showerhead 120 has two separate pathways or gas lines (not shown), which allow two gases to be separately introduced into the chamber 100 without pre-mixing. Details of the showerhead 120 have been disclosed in commonly-assigned U.S. patent application Ser. No. 09/098,969, entitled “Dual Gas Faceplate for a Showerhead in a Semiconductor Wafer Processing System”, filed Jun. 16, 1998, which is herein incorporated by reference.

The showerhead 120 is connected to a gas panel 130, which controls and supplies various gases used in different steps of the process sequence. During wafer processing, a purge gas supply 104 may also provide a purge gas, for example, an inert gas, around the bottom of the pedestal 150, to minimize undesirable deposit formation on the backside of the pedestal 150.

The showerhead 120 and the wafer support pedestal 150 also form a pair of spaced apart electrodes. When an electric field is generated between these electrodes, the process gases introduced into the chamber 100 are ignited into a plasma 180. The electric field can be generated, for example, by connecting the wafer support pedestal 150 to a source of radio frequency (RF) power (not shown) through a matching network (not shown). Alternatively, the RF power source and matching network may be coupled to the showerhead 120, or coupled to both the showerhead 120 and the wafer support pedestal 150.

Plasma enhanced chemical vapor deposition (PECVD) techniques promote excitation and/or disassociation of the reactant gases by the application of the electric field to the reaction zone near the substrate surface, creating a plasma 180 of reactive species. The reactivity of the species in the plasma 180 reduces the energy required for a chemical reaction to take place, in effect lowering the required temperature for such PECVD processes.

Proper control and regulation of the gas flows through the gas panel 130 is performed by mass flow controllers (not shown) and a controller unit 110, such as a computer. The showerhead 120 allows process gases from the gas panel 130 to be uniformly introduced and distributed in the process chamber 100. Illustratively, the control unit 110 comprises a central processing unit (CPU) 112, support circuitry 114, and memories containing associated control software 116. The control unit 110 is responsible for automated control of the numerous steps required for wafer processing—such as wafer transport, gas flow control, temperature control, chamber evacuation, and other steps. The control unit 110 may be one of any form of general purpose computer processor that can be used in an industrial setting for controlling various chambers and sub-processors. The computer processor may use any suitable memory, such as random access memory, read only memory, floppy disk drive, hard disk, or any other form of digital storage, local or remote. Various support circuits may be coupled to the computer processor for supporting the processor in a conventional manner. Software routines as required may be stored in the memory or executed by a second processor that is remotely located. Bi-directional communications between the control unit 110 and the various components of the system 10 are handled through numerous signal cables collectively referred to as signal buses 118, some of which are illustrated in FIG. 1.

Ti and TiN Layer Formation

The following embodiments are methods for titanium and/or titanium nitride (Ti/TiN) formation, which advantageously provide a Ti and/or TiN film stack with improved reliability and good step coverage for the both the Ti and/or TiN films.

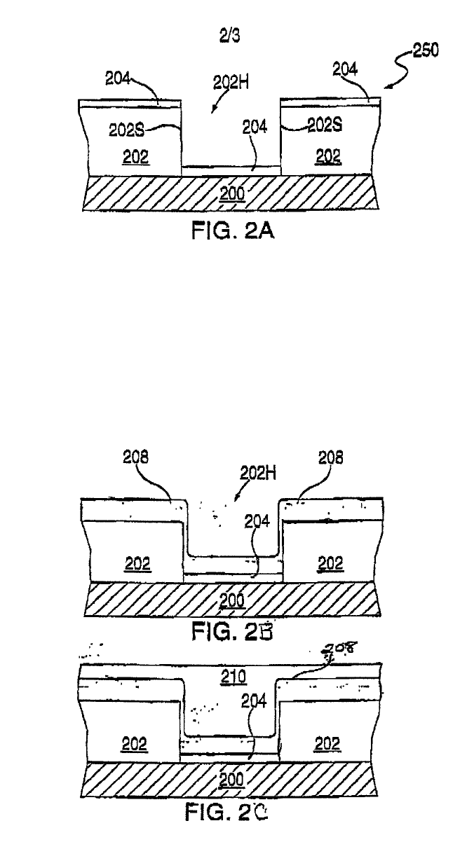

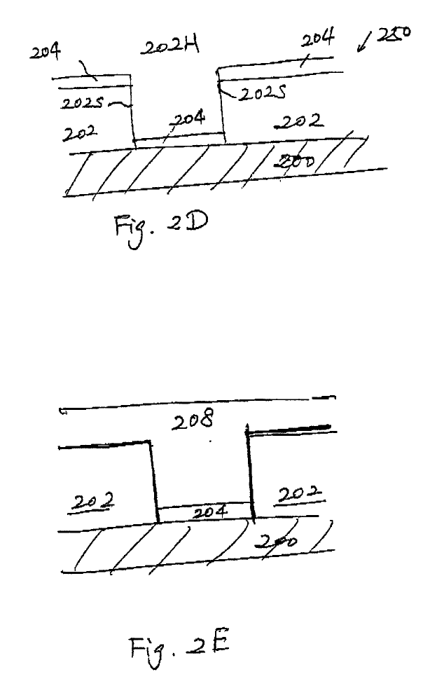

FIGS. 2a-2e illustrate one preferred embodiment of the present invention in which Ti and TiN films are formed. In general, the substrate 200 refers to any workpiece upon which film processing is performed, and a substrate structure 250 is used to generally denote the substrate 200 as well as other material layers formed on the substrate 200. Depending on the specific stage of processing, the substrate 200 may be a silicon semiconductor wafer, or other material layer, which has been formed on the wafer. FIG. 2a, for example, shows a cross-sectional view of a substrate structure 250, having a material layer 202 thereon. In this particular illustration, the material layer 202 may be an oxide (e.g., silicon dioxide). The material layer 202 has been conventionally formed and patterned to provide a contact hole 202H extending to the top surface 200T of the substrate 200.

A Ti film 204 is formed on the substrate structure 250. The Ti layer 204 is formed by depositing a Ti layer using, for example, plasma-enhanced decomposition of a gas mixture comprising a titanium compound such as titanium tetrachloride (TiCl₄) and a hydrogen-containing compound. The Ti film can be deposited in a process chamber 100 similar to that shown in FIG. 1. In general, the decomposition of the titanium compound may be performed at a substrate temperature of about 400° C. to about 700° C., a chamber pressure of about 5 torr to about 30 torr, a titanium compound flow rate of about 50 mg/min and above, a hydrogen gas flow rate of about 2000 sccm to about 4000 sccm, an RF power of about 1 watt/cm² to about 3 watts/cm², and a plate spacing of about 300 mils to about 500 mils. Dilutant gases such as hydrogen (H₂), argon (Ar), helium (He), or combinations thereof may be added to the gas mixture. The above deposition parameters provide a deposition rate for the titanium of about 1 Å/sec to about 3 Å/sec.

The deposited Ti film 204 also contacts a portion of the substrate 200 at the bottom 200T of the contact hole 202H. Due to the non-conformal nature of the plasma deposited Ti film 204, the sidewalls 202S of the contact hole 202H are typically covered by a much thinner film of titanium than is deposited on the bottom 200T of the contact hole 202H. The thickness of titanium deposited in the bottom 200T of the contact hole 202H may be controlled by the adjusting the process time.

The titanium film is deposited to a thickness of less than about 100 Å. Thereafter the titanium film is treated with a hydrogen/nitrogen-containing plasma. The Ti film can be treated in a process chamber 100 similar to that shown in FIG. 1. In general, the titanium layer plasma treatment may be performed at a substrate temperature of about 450° C. to about 680° C., a chamber pressure of about 5 torr to about 30 torr, a nitrogen/hydrogen gas flow ratio of about 0.1 to about 1, an RF power of about 0.5 watts/cm² to about 10 watts/cm², and a plate spacing of about 300 mils to about 500 mils. Hydrogen (H₂), nitrogen (N₂), ammonia (NH₃), and hydrazine (N₂H₄), among others, may be used for the nitrogen/hydrogen plasma. Dilutant gases such as hydrogen (H₂), argon (Ar), helium (He), or combinations thereof may be added to the gas mixture. The titanium film is plasma treated for about 5 seconds to about 60 seconds.

After the titanium layer is plasma treated, another later of titanium is formed thereon and then plasma treated according to the process parameters detailed above. The alternating deposition/plasma treatment steps are preformed until a desired layer thickness is achieved. Alternatively, when the Ti layer is formed on a silicon substrate a layer of TiSiₓ may be formed during the first plasma treatment step. After the first cycle, subsequent Ti depositions followed by plasma treatments with the H₂/N₂ gases can result in the formation of a composite titanium/titanium nitride layer. The titanium silicide thickness varies as a function of the plasma treatment time as well as the plasma treatment temperature.

The as-deposited plasma treated titanium layer when formed on silicon dioxide (SᵢO₂) has a resistivity of less than about 70 μω-cm, which is about 3 times smaller than the resistivity of films obtained using standard CVD processes (typically about 200 μω-cm). Additionally, the as-deposited Ti layers have better sheet resistance uniformity across the deposited film.

After the formation of the Ti layer 204, a TiN layer 208 is deposited in the contact hole 202H, as illustrated in FIG. 2b. The TiN film 208 can be formed, for example, by CVD using a reaction of TiCl₄ and NH₃ in the chamber 100 of FIG. 1. In one embodiment, helium (He) and nitrogen (N₂) are introduced into the chamber 100, along with TiCl₄, via one pathway (gas line) of the showerhead 120. NH₃, along with N₂, is introduced into the chamber 100 via the second pathway of the showerhead 120. He and argon (Ar), or other inert gases, may also be used, either singly or in combination (i.e., as a gas mixture) within either gas line of the showerhead 120. A bottom inert gas purge flow (e. g., Ar) of about 500 sccm is also established through a separate gas line and gas supply 104 provided at the bottom of the chamber 100.

Typically, the reaction can be performed at a TiCl₄ flow rate of about 50 mg/min to about 350 mg/min, and a NH₃ flow of about 100 sccm to about 500 sccm, introduced into the chamber 100 though the first pathway of the showerhead 120. A total pressure range of about 5 torr to about 30 torr and a pedestal temperature between about 400° C. to about 700° C. may be used. The above deposition parameters provide a deposition rate for the titanium nitride of about 5 Å/sec to about 13 Å/sec.

The titanium nitride film is deposited to a thickness of less than about 300 Å. Thereafter the titanium nitride film is treated with a hydrogen/nitrogen-containing plasma. The TiN film can be treated in a process chamber 100 similar to that shown in FIG. 1. In general, the titanium nitride layer plasma treatment may be performed at a substrate temperature of about 400° C. to about 700° C., a chamber pressure of about 5 torr to about 30 torr, a nitrogen/hydrogen gas flow ratio of about 0.1 to about 1, an RF power of about 0.5 watts/cm² to about 10 watts/cm², and a plate spacing of about 300 mils to about 500 mils. Hydrogen (H₂), nitrogen (N₂), ammonia (NH₃), and hydrazine (N₂H₄), among others, may be used for the nitrogen/hydrogen plasma. Dilutant gases such as hydrogen (H₂), argon (Ar), helium (He), or combinations thereof may be added to the gas mixture. The titanium nitride film is plasma treated for about 5 seconds to about 60 seconds.

After the titanium nitride layer is plasma treated, another layer of titanium nitride is formed thereon and then plasma treated according to the process parameters detailed above. The alternating deposition/plasma treatment steps are preformed until a desired layer thickness is achieved.

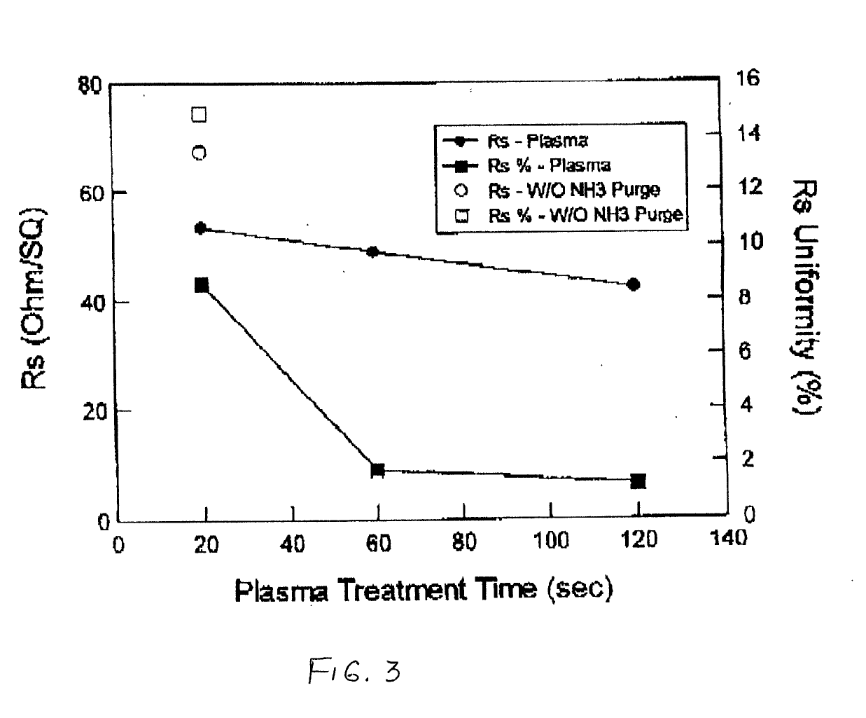

FIG. 3 is a graph of the resistivity and sheet resistance uniformity plotted as a function of the plasma treatment time. As shown in the graph of FIG. 3, an as-deposited plasma treated titanium nitride layer having a thickness of about 300 Å has a resistivity of less than about 20 ω-sq and a sheet resistance uniformity of 8-10% as compared to a resistivity of about 75 ω-sq and a sheet resistance uniformity of about 14% for non-plasma treated layers.

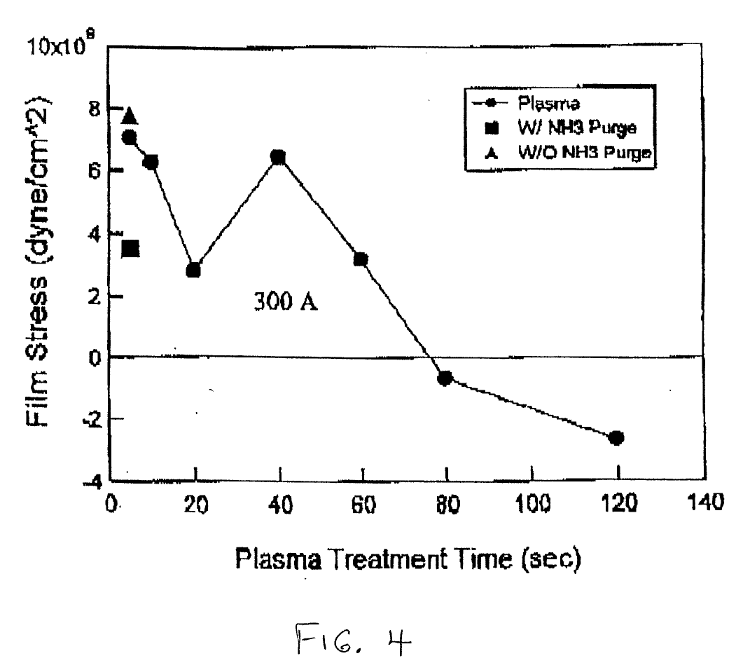

FIG. 4 is a graph of the film stress plotted as a function of the plasma treatment time. Referring to FIG. 4, an as-deposited TiN layer having a thickness of about 300 Å has reduced stress. In particular, TiN layers formed using previous deposition processes typically have tensile stresses of about 3-8×10⁹ dynes/cm². In contrast, TiN layers formed according to the process conditions described herein have a compressive stress of about −1-3×10⁹ dynes/cm².

Thereafter, as illustrated in FIG. 2c, a tungsten (W) plug 210 is formed on the TiN layer 208 of FIG. 2b. The W plug 210 may be formed from, for example, a reaction between WF₆ and H₂. Adhesion of the W-plug layer is improved by the presence of the TiN layer 208.

Alternatively, a TiN layer deposited according to the process parameters described above can also be used to form a TiN-plug contact 208 on a Ti layer 204, as shown in FIGS. 2d-2e. The TiN-plug contact 208 has good adhesion to Ti layer 204.

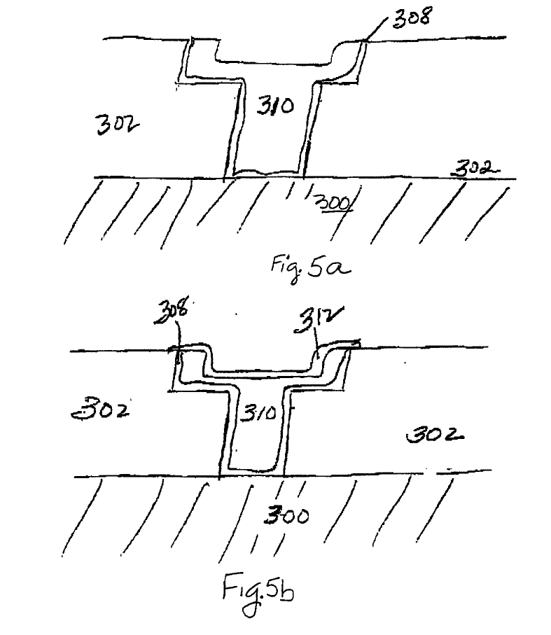

FIGS. 5a-5b illustrate schematic cross-sectional views of a substrate 300 at different stages of a capacitive memory cell fabrication sequence. Depending on the specific stage of processing, substrate 300 may correspond to a silicon wafer, or other material layer that has been formed on the silicon wafer. Alternatively, the substrate may have integrated circuit structures (not shown) such as logic gates formed on regions thereof.

FIG. 5a, for example, illustrates a cross-sectional view of a silicon substrate 300 having a material layer 302 formed thereon. The material layer 302 may be an oxide (e.g., fluorosilicate glass (FSG), undoped silicate glass (USG), organosilicates) or a silicon carbide material. Material layer 302 preferably has a low dielectric constant (e.g., dielectric constant less than about 5). The thickness of material layer 302 is variable depending on the size of the structure to be fabricated. Typically, material layer 302 has a thickness of about 1,000 Å to about 20,000 Å. Apertures 301 having widths less than about 0.5 μm (micrometer) wide and depths of about 0.5 μm to about 2 μm, providing aspect ratio structures in a range of about 1:1 to about 4:1 are formed therein.

A bottom electrode 308 is conformably deposited along the sidewalls and bottom surface of aperture 301. The bottom electrode 308 is conformably deposited using conventional PVD or CVD techniques. An example of a suitable electrode material is TaN, among others. The thickness of the bottom electrode 308 is variable depending on the size of the structure to be fabricated. Typically, the bottom electrode 308 has a thickness of about 1,000 Å to about 10,000 Å.

Above the bottom electrode 308 is deposited a Ta₂O₅ memory cell dielectric layer 310. The Ta₂O₅ memory cell dielectric layer 310 is conformably deposited using conventional CVD. The thickness of the Ta₂O₅ memory cell dielectric layer 310 is variable depending on the size of the structure to be fabricated. Typically, the Ta₂O₅ memory cell dielectric layer 310 has a thickness of about 100 Å to about 500 Å.

Referring to FIG. 5b, the capacitive memory cell is completed by conformably depositing a TiN top electrode 312 on the Ta₂O₅ memory cell dielectric layer 310. The TiN top electrode 312 is conformably deposited using CVD techniques according to the process parameters described above. The thickness of the TiN top electrode 312 is variable depending on the size of the structure to be fabricated. Typically, the TiN top electrode 312 has a thickness of about 1,000 Å to about 10,000 Å.

Although several preferred embodiments, which incorporate the teachings of the present invention have been shown and described in detail, those skilled in the art can readily devise many other varied embodiments that still incorporate these teachings.

What is claimed is:

1. A method of film deposition, comprising:
forming a titanium structure on a substrate by sequentially depositing and than plasma treating a thin films of titanium, wherein the titanium is deposited from a reaction of titanium tetrachloride (TiCl₄) and hydrogen (H₂) in the presence of an electric field, and wherein the titanium is plasma treated using a nitrogen/hydrogen-containing plasma having a nitrogen to hydrogen flow ratio of about 0.1 to about 1.

2. The method of claim 1 wherein the titanium is treated for about 5 seconds to about 60 seconds.

3. The method of claim 1 wherein the nitrogen/hydrogen-containing plasma has a power density of about 0.5 Watts/cm² to about 10 Watts/cm².

4. The method of claim 1 wherein the nitrogen/hydrogen plasma comprises at least one gas selected from the group consisting of hydrogen (H₂), nitrogen (N₂), ammonia (NH₃), and hydrazine (N₂H₄), among others.

5. The method of claim 1 wherein the titanium structure has a thickness of about 300 Å to about 500 Å.

6. The method of claim 1 wherein the titanium is plasma treated at a temperature of about 400° C. to about 700° C.

7. The method of claim 1 wherein the substrate comprises silicon and titanium silicide (TiSiₓ) is formed during a first titanium deposition/plasma treatment step.

8. A method of film deposition, comprising:
forming a titanium nitride structure on a substrate by sequentially depositing and than plasma treating a thin films of titanium nitride, wherein the titanium nitride is deposited by thermally decomposing a gas mixture comprising titanium tetrachloride (TiCl₄) and ammonia (NH₃), and wherein the titanium nitride is plasma treated using a nitrogen/hydrogen-containing plasma having a nitrogen to hydrogen flow ratio of about 0.1 to about 1.

9. The method of claim 8 wherein the titanium nitride is treated for about 5 seconds to about 60 seconds.

10. The method of claim 8 wherein the nitrogen/hydrogen-containing plasma has a power density of about 0.5 Watts/cm² to about 10 Watts/cm².

11. The method of claim 8 wherein the nitrogen/hydrogen plasma comprises at least one gas selected from the group consisting of hydrogen (H₂), nitrogen (N₂), ammonia (NH₃), and hydrazine (N₂H₄), among others.

12. The method of claim 8 wherein the titanium nitride layer has a thickness of about 300 Å to about 1000 Å.

13. The method of claim 8 wherein the titanium nitride is plasma treated at a temperature of about 400° C. to about 700° C.

14. A method of forming a barrier layer structure, comprising:
forming a titanium structure on a substrate by sequentially depositing and than plasma treating a thin films of titanium, wherein the titanium is deposited from a reaction of titanium tetrachloride (TiCl₄) and hydrogen (H₂) in the presence of an electric field, and wherein the titanium is plasma treated using a nitrogen/hydrogen-containing plasma having a nitrogen to hydrogen flow ratio of about 0.1 to about 1; and
forming a titanium nitride structure on titanium structure by sequentially depositing and than plasma treating a thin films of titanium nitride, wherein the titanium nitride is deposited by thermally decomposing a gas mixture comprising titanium tetrachloride (TiCl₄) and ammonia (NH₃), and wherein the titanium nitride is plasma treated using a nitrogen/hydrogen-containing plasma having a nitrogen to hydrogen flow ratio of about 0.1 to about 1.

15. The method of claim 14 wherein the titanium is treated for about 5 seconds to about 60 seconds.

16. The method of claim 14 wherein the nitrogen/hydrogen-containing plasma has a power density of about 0.5 Watts/cm² to about 10 Watts/cm².

17. The method of claim 14 wherein the nitrogen/hydrogen plasma comprises at least one gas selected from the group consisting of hydrogen (H₂), nitrogen (N₂), ammonia (NH₃), and hydrazine (N₂H₄), among others.

18. The method of claim 14 wherein the titanium structure has a thickness of about 300 Å to about 500 Å.

19. The method of claim 14 wherein the titanium is plasma treated at a temperature of about 400° C. to about 700° C.

20. The method of claim 14 wherein the substrate comprises silicon and titanium silicide (TiSiₓ) is formed during a first titanium deposition/plasma treatment step.

21. The method of claim 14 wherein the titanium nitride is treated for about 5 seconds to about 60 seconds.

22. The method of claim 14 wherein the nitrogen/hydrogen-containing plasma has a power density of about 0.5 Watts/cm² to about 10 Watts/cm².

23. The method of claim 14 wherein the nitrogen/hydrogen plasma comprises at least one gas selected from the group consisting of hydrogen (H₂), nitrogen (N₂), ammonia (NH₃), and hydrazine (N₂H₄), among others.

24. The method of claim 14 wherein the titanium nitride layer has a thickness of about 300 Å to about 1000 Å.

25. The method of claim 14 wherein the titanium nitride is plasma treated at a temperature of about 400° C. to about 700° C.

26. A method of forming an electrode on a capacitive device, comprising:
providing a substrate having a bottom electrode and a memory cell dielectric formed thereon,
forming a titanium structure on the memory cell dielectric by sequentially depositing and than plasma treating a thin films of titanium, wherein the titanium is deposited from a reaction of titanium tetrachloride (TiCl₄) and hydrogen (H₂) in the presence of an electric field, and wherein the titanium is plasma treated using a nitrogen/hydrogen-containing plasma having a nitrogen to hydrogen flow ratio of about 0.1 to about 1; and
forming a titanium nitride structure on titanium structure by sequentially depositing and than plasma treating a thin films of titanium nitride, wherein the titanium nitride is deposited by thermally decomposing a gas mixture comprising titanium tetrachloride (TiCl₄) and ammonia (NH₃), and wherein the titanium nitride is plasma treated using a nitrogen/hydrogen-containing plasma having a nitrogen to hydrogen flow ratio of about 0.1 to about 1.

27. The method of claim 26 wherein the titanium is treated for about 5 seconds to about 60 seconds.

28. The method of claim 26 wherein the nitrogen/hydrogen-containing plasma has a power density of about 0.5 Watts/cm² to about 10 Watts/cm².

29. The method of claim 26 wherein the nitrogen/hydrogen plasma comprises at least one gas selected from the group consisting of hydrogen (H₂), nitrogen (N₂), ammonia (NH₃), and hydrazine (N₂H₄), among others.

30. The method of claim 26 wherein the titanium structure has a thickness of about 300 Å to about 500 Å.

31. The method of claim 26 wherein the titanium is plasma treated at a temperature of about 400° C. to about 700° C.

32. The method of claim 26 wherein the titanium nitride is treated for about 5 seconds to about 60 seconds.

33. The method of claim 26 wherein the nitrogen/hydrogen-containing plasma has a power density of about 0.5 Watts/cm² to about 10 Watts/cm².

34. The method of claim 26 wherein the nitrogen/hydrogen plasma comprises at least one gas selected from the group consisting of hydrogen (H₂), nitrogen (N₂), ammonia (NH₃), and hydrazine (N₂H₄), among others.

35. The method of claim 26 wherein the titanium nitride layer has a thickness of about 300 Å to about 1000 Å.

36. The method of claim 26 wherein the titanium nitride is plasma treated at a temperature of about 400° C. to about 700° C.
